(19) United States
(12) Patent Application Publication
(10) Pub. No.: US 2025/0239519 A1
(43) Pub. Date: Jul. 24, 2025

(54) METHOD OF MANUFACTURING METAL STRUCTURE HAVING FUNNEL-SHAPED INTERCONNECT

(71) Applicant: NANYA TECHNOLOGY CORPORATION, NEW TAIPEI CITY (TW)

(72) Inventor: MIN-CHUNG CHENG, TAOYUAN CITY (TW)

(21) Appl. No.: 19/172,879

(22) Filed: Apr. 8, 2025

Related U.S. Application Data
(63) Continuation of application No. 17/879,981, filed on Aug. 3, 2022.

(51) Int. Cl. H01L 23/528; H01L 21/768; H01L 23/532

(52) U.S. Cl. CPC H01L 23/528; H01L 21/76814; H01L 21/76831; H01L 21/76843; H01L 21/76877; H01L 23/53238

(57) ABSTRACT

The present application provides a semiconductor device and a method of manufacturing the semiconductor device. The semiconductor device includes a substrate and a wiring structure. The wiring structure includes at least one metal interconnect disposed on the substrate, at least one conductive feature disposed on the metal interconnect, and at least one diffusing barrier liner surrounding the conductive feature. The conductive feature has a head portion and a neck portion sandwiched between the metal interconnect and the head portion. The neck portion has a first critical dimension, which gradually decreases at positions of increasing distance from the head portion.

### CROSS-REFERENCE TO RELATED APPLICATION

This application is a continuation application of U.S. Non-Provisional application Ser. No. 17/879,981 filed Aug. 3, 2022, which is incorporated herein by reference in its entirety.

### TECHNICAL FIELD

The present disclosure relates to a semiconductor device and a method of manufacturing the same, and more particularly, to a semiconductor device whose metal structure has a funnel-shaped interconnect and a method of manufacturing the same.

### DISCUSSION OF THE BACKGROUND

Process flows for fabrication of integrated semiconductor circuits may include front end of line (FEOL), middle-end-of-line (MEOL), and back-end-of-line (BEOL) processes. The FEOL process may include wafer preparation, isolation, well formation, gate patterning, spacing, extension and source/drain implantation, silicide formation, and dual stress liner formation. The MEOL process may include gate contact formation. The BEOL process may include a series of wafer processing steps for interconnection of semiconductor devices created during the FEOL and MEOL processes. Successful fabrication and qualification of modern semiconductor chip products requires consideration of interplay between materials and the processes employed.

This Discussion of the Background section is provided for background information only. The statements in this Discussion of the Background are not an admission that the subject matter disclosed in this Discussion of the Background section constitutes prior art to the present disclosure, and no part of this Discussion of the Background section may be used as an admission that any part of this application, including this Discussion of the Background section, constitutes prior art to the present disclosure.

### SUMMARY

One aspect of the present disclosure provides a semiconductor device. The semiconductor device includes a substrate and a wiring structure. The wiring structure includes at least one metal interconnect, at least one conductive feature and at least one diffusion barrier liner. The metal interconnect is disposed on the substrate, and the conductive feature, surrounded by the diffusion barrier liner, is disposed on the metal interconnect and includes a head portion and a neck portion sandwiched between the metal interconnect and the head portion. The neck portion has a first critical dimension, which gradually decreases at positions of increasing distance from the head portion.

In some embodiments, an included angle between the neck portion and the metal interconnect is less than 90 degrees.

In some embodiments, the diffusion barrier liner has a first thickness, wherein smaller values of the included angle correspond to greater values of the first thickness of the diffusion barrier liner.

In some embodiments, the neck portion has a second thickness, and the head portion has a third thickness, greater than the second thickness.

In some embodiments, the head portion has a second critical dimension greater than the first critical dimension.

In some embodiments, the semiconductor device further includes an isolation layer surrounding the head portion of the conductive feature, and a block layer surrounding the neck portion of the conductive feature.

In some embodiments, the block layer includes an underlying layer in contact with the metal interconnect and an overlying layer between the underlying layer and the isolation layer.

In some embodiments, the underlying layer has a first permittivity, and the overlying layer has a second permittivity greater than the first permittivity.

In some embodiments, the diffusion barrier liner is sandwiched between the conductive feature and the metal interconnect, between the conductive feature and the block layer, and between the conductive feature and the isolation layer.

In some embodiments, the semiconductor device further includes an insulative layer surrounding the metal interconnect and an adhesion liner interposed between the metal interconnect and substrate and between the metal interconnect and the insulative layer.

In some embodiments, the head portion and the neck portion of the conductive feature are integrally formed.

In some embodiments, the metal interconnect and the conductive feature have identical conductive materials.

One aspect of the present disclosure provides a method of manufacturing a semiconductor. The method includes steps of providing a plurality of metal interconnects on a substrate; disposing a block layer on the metal interconnects; disposing an isolation layer on the block layer; forming at least one trench in the isolation layer; forming at least one hole penetrating through the block layer and connecting to the trench, wherein the hole has a width, which gradually increases at positions of increasing distance from the metal interconnect; depositing a diffusion barrier layer in the trench and the hole; and depositing a conductive material on the diffusion barrier layer.

In some embodiments, an included angle between the block layer and the one of the metal interconnects is greater than 90 degrees.

In some embodiments, in a predetermined deposition time, greater values of the width corresponding to greater values of a thickness of the diffusion barrier layer.

In some embodiments, the creation of the hole penetrating through the block layer and connecting to the trench includes steps of forming a sacrificial layer on the isolation layer and in the trench; performing a lithography process to remove a portion of the sacrificial layer in the trench and over the metal interconnect, and thus form sacrificial blocks; and performing a removal process to remove a portion of the block layer exposed through the trench.

In some embodiments, the removal process uses a process gas that comprises a mixture of carbon tetrafluoride and nitrogen.

In some embodiments, a ratio of the carbon tetrafluoride to the nitrogen is in a range between 1.5:1 and 1.8:1.

In some embodiments, greater values of the ratio correspond to greater values of the width of the hole.

In some embodiments, an operating pressure for conducting the removal process is in a range between 50 and 150 metric tons.

In some embodiments, greater values of the pressure correspond to greater values of the width of the hole.

In some embodiments, a direct current superposition voltage for conducting the removal process is in a range between 100 and 300 volts.

In some embodiments, greater values of the direct current superposition voltage correspond to smaller values of the width of the hole.

With the above-mentioned configurations of the semiconductor device, the thickness of the neck portion of the conductive feature connecting the head portion of the conductive feature to the metal interconnect can be adjusted by precisely controlling an etchant, the pressure, and the direct current superposition voltage applied to a chamber for conducting an etching process to remove portions of the block layer for filling the neck portion; therefore, a resistance of the neck portion and thus a resistance of the wiring structure formed during the back-line-of-line processes can be effectively controlled.

The foregoing has outlined rather broadly the features and technical advantages of the present disclosure in order that the detailed description of the disclosure that follows may be better understood. Additional features and technical advantages of the disclosure are described hereinafter, and form the subject of the claims of the disclosure. It should be appreciated by those skilled in the art that the concepts and specific embodiments disclosed may be utilized as a basis for modifying or designing other structures, or processes, for carrying out the purposes of the present disclosure. It should also be realized by those skilled in the art that such equivalent constructions do not depart from the spirit or scope of the disclosure as set forth in the appended claims.

### BRIEF DESCRIPTION OF THE DRAWINGS

A more complete understanding of the present disclosure may be derived by referring to the detailed description and claims. The disclosure should also be understood to be coupled to the figures' reference numbers, which refer to similar elements throughout the description.

FIG. 1A is a cross-sectional view of a semiconductor device in accordance with some embodiments of the present disclosure.

FIG. 1B is a cross-sectional view of a semiconductor device in accordance with some embodiments of the present disclosure.

FIG. 2 is a close-up view of an area A of FIG. 1A.

FIG. 3 is a flow diagram illustrating a method of manufacturing a semiconductor device in accordance with some embodiments of the present disclosure.

FIGS. 4 illustrates a cross-sectional view of an intermediate stage in the formation of a semiconductor device in accordance with some embodiments of the present disclosure.

FIGS. 5A and 5B illustrate cross-sectional views of a substrate in according with some embodiments of the present disclosure.

FIGS. 6 to 14 illustrate cross-sectional views of intermediate stages in the formation of a semiconductor device in accordance with some embodiments of the present disclosure.

FIG. 15 is a close-up view of an area B of FIG. 14.

FIGS. 16 and 17 illustrate cross-sectional views of intermediate stages in the formation of a semiconductor device in accordance with some embodiments of the present disclosure.

### DETAILED DESCRIPTION

Embodiments, or examples, of the disclosure illustrated in the drawings are described below using specific language. It shall be understood that no limitation of the scope of the disclosure is hereby intended. Any alteration or modification of the described embodiments, and any further applications of principles described in this document, are to be considered as normally occurring to one of ordinary skill in the art to which the disclosure relates. Reference numerals may be repeated throughout the embodiments, but this does not necessarily mean that feature(s) of one embodiment apply to another embodiment, even if they share the same reference numeral.

It shall be understood that, although the terms first, second, third, etc. may be used herein to describe various elements, components, regions, layers or sections, these elements, components, regions, layers or sections are not limited by these terms. Rather, these terms are merely used to distinguish one element, component, region, layer or section from another element, component, region, layer or section.

Thus, a first element, component, region, layer or section discussed below could be termed a second element, component, region, layer or section without departing from the teachings of the present inventive concept.

The terminology used herein is for the purpose of describing particular example embodiments only and is not intended to be limiting to the present inventive concept. As used herein, the singular forms “a,” “an” and “the” are intended to include the plural forms as well, unless the context clearly indicates otherwise. It shall be understood that the terms “comprises” and “comprising,” when used in this specification, point out the presence of stated features, integers, steps, operations, elements, or components, but do not preclude the presence or addition of one or more other features, integers, steps, operations, elements, components, or groups thereof.

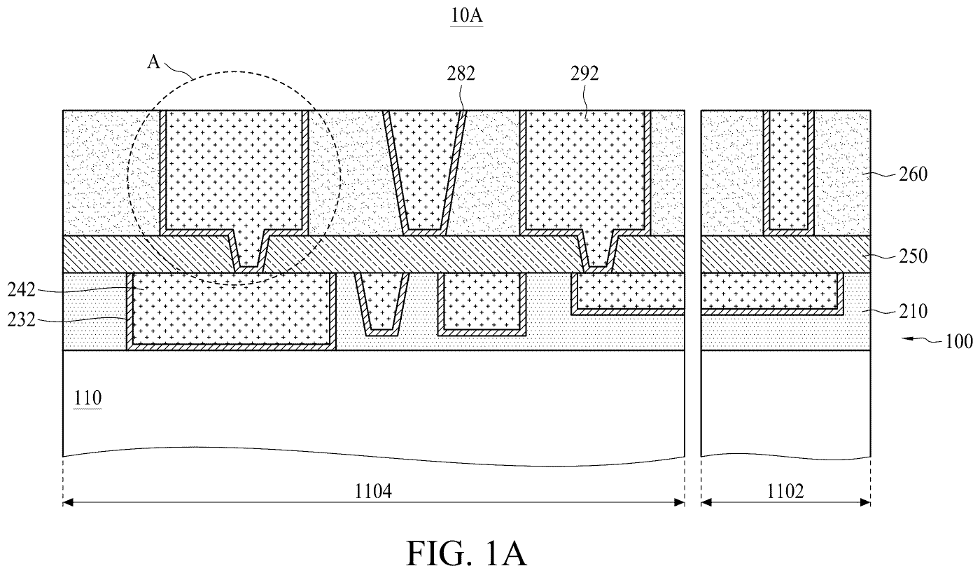

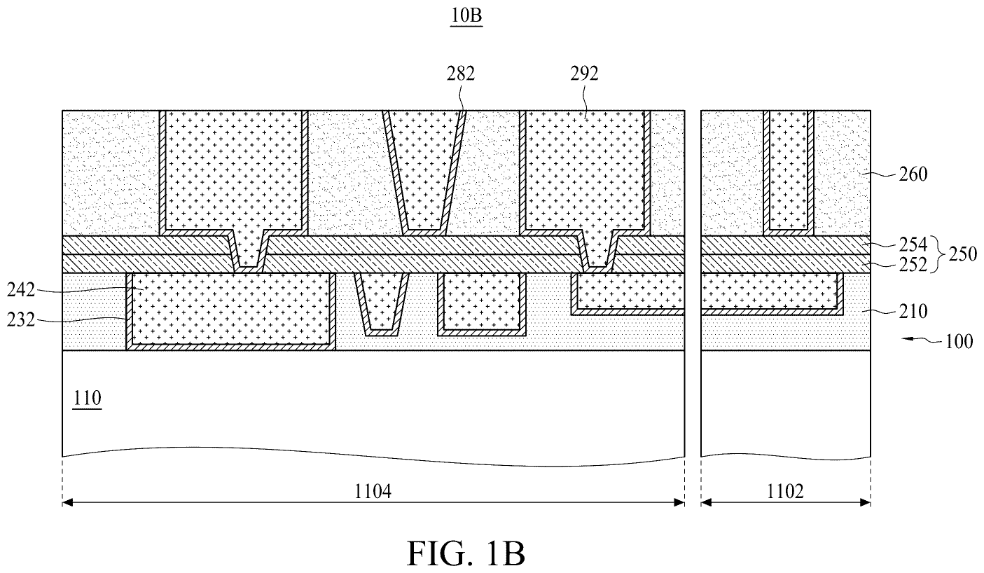

FIG. 1A is a cross-sectional view of a semiconductor device 10A in accordance with some embodiments of the present disclosure. Referring to FIG. 1A, the semiconductor device 10A includes a wiring structure 100 and a substrate 110; the wiring structure 100 is disposed on the substrate 110 for electrically connecting multiple main components (not shown) formed in or on the substrate 110. The substrate 110 may extend to comprise an array area 1102 and a periphery region 1104 that laterally encloses the array area 1102, and the main components, such as planar access devices, planar access transistors, or recessed access device (RAD) transistors, are located in the array area 1102. The main components are formed during front-end-of-line processes, and the wiring structure 100 is formed during back-end-of-line processes.

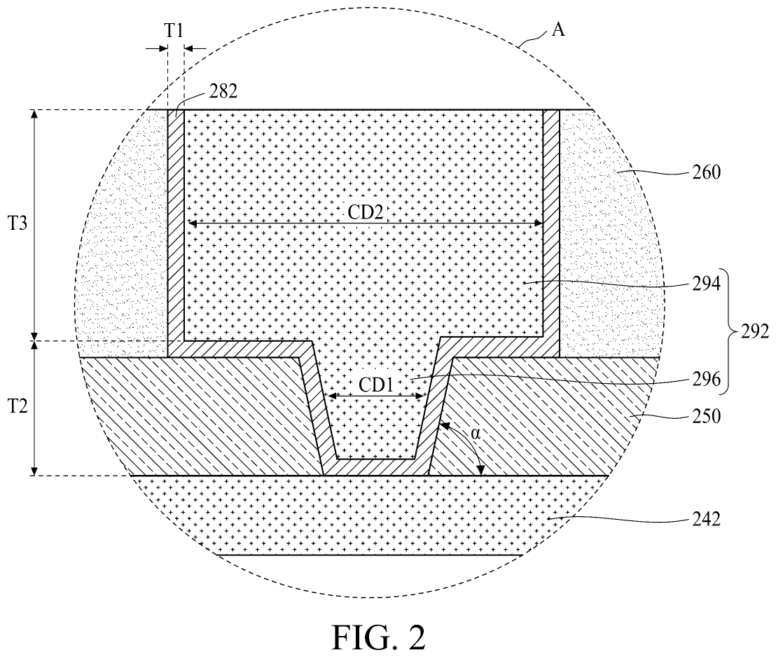

The wiring structure 100 includes one or more metal interconnects 242, one or more conductive features 292 in contact with the metal interconnects 242, and one or more diffusion barrier lines 282 surrounds the conductive features 292. Referring to FIG. 2, the conductive feature 292, physically connected to the diffusion barrier liner 282, has a head portion 294 and a neck portion 296 sandwiched between the metal interconnect 242 and the head portion 294. The head portion 294 and the neck portion 296 of the conductive feature 292 may be integrally formed.

The neck portion 296, connecting the head portion 294 to the metal interconnect 242, has a first critical dimension CD1, which gradually decreases at positions of increasing distance from the head portion 294. That is, the neck portion 296 of the conductive feature 292 has a funnel shape when viewed in a cross-sectional view. In addition, an included angle α, between the neck portion 296 of the conductive feature 292 and the metal interconnect 242, is less than 90 degrees. Furthermore, the diffusion barrier liner 282 has a first thickness, the neck portion 296 of the conductive feature 292 has a second thickness T2, and the head portion 294 thereof has a third thickness T3 greater than the second thickness T2. Notably, in the predetermined time for deposition the diffusion barrier liner 282, greater values of the included angle α correspond to smaller values of the first thickness T1. For example, the first thickness T1 is about 27 nanometers when the included angle α is equal to 71.1 degrees, and the first thickness T1 is about 17 nanometers when the included angle α is 85.5 degrees. Smaller values of the first thickness T1 correspond to less resistance of the diffusion barrier liner 282.

Referring again to FIG. 1A, the wiring structure 100 further includes an insulative layer 210, a block layer 250 and an isolation layer 260 sequentially stacked on the substrate 110. The metal interconnects 242 are surrounded by the insulative layer 210, and the conductive features 292 are surrounded by the block layer 250 and the isolation layer 260. Specifically, the neck portion 296 of the conductive feature 292 penetrates through the block layer 250 and connects to the head portion 294 in the isolation layer 260. In some embodiments, the head portion 294 of the conductive feature 292 is substantially rectangular in shape when viewed in the cross-sectional view. Notably, the block layer 250 may be a single-layered structure including oxide or nitride. In alternative embodiments, the block layer 250 may comprise a multi-layered structure including one or more insulating materials, as shown in FIG. 1B. In FIG. 1B, the block layer 250 of the semiconductor device 10B includes an underlying layer 252 and an overlying layer 254 staked on the underlying layer 252. The underlying layer 252 and the overlying layer 254 may have different permittivities. In some embodiments, the underlying layer 252 has a first permittivity, and the overlying layer 254 has a second permittivity greater than the first permittivity.

The wiring structure 100 can optionally include an adhesion liner 232 interposed between the insulative layer 210 and the metal interconnect 242 and between the substrate 110 and the metal interconnect 242. The adhesion liner 232 achieves a good adhesion to the substrate 110 and the insulative layer 210, thereby preventing the metal interconnect 242 from flaking or spalling from the substrate 110 and the insulative layer 210. The wiring structure 100 may also include a diffusion barrier liner 282 sandwiched between the block layer 250 and the conductive feature 292 and between the isolation layer 260 and the conductive feature 292. The diffusion barrier liner 282, used to facilitate improved quality control of the growing of the conductive features 292, is optional.

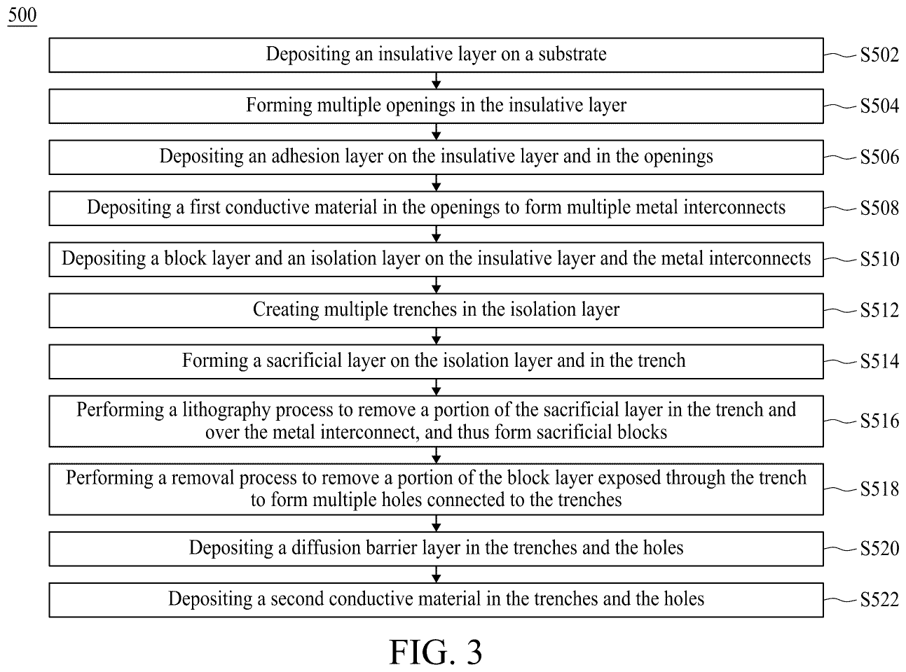

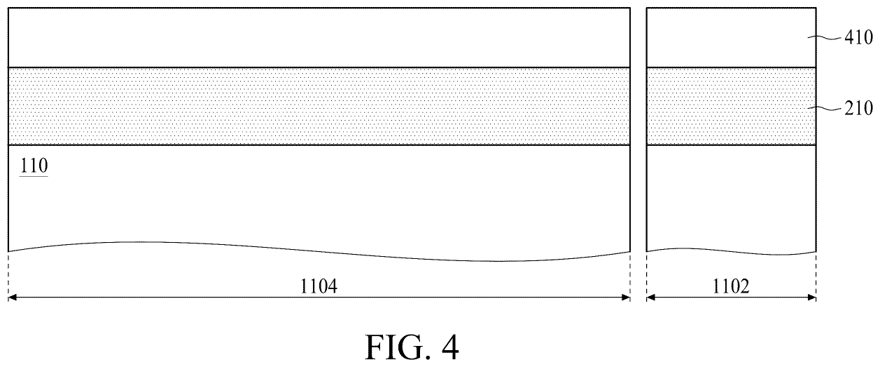

FIG. 3 is a flow diagram illustrating a method 500 of manufacturing a semiconductor device 10A/10B in accordance with some embodiment of the present disclosure. FIG. 4 and FIGS. 6 to 17 are schematic diagrams illustrating various fabrication stages constructed according to the method 500 for manufacturing the semiconductor device 10 in accordance with some embodiments of the present disclosure. The stages shown in FIG. 4 and FIGS. 6 to 17 are also illustrated schematically in the flow diagram in FIG. 3. In the subsequent discussion, the fabrication stages shown in FIG. 4 and FIGS. 6 to 17 are discussed in reference to the process steps shown in FIG. 3.

Referring to FIG. 4, an insulative layer 210 is disposed on a substrate 110 according to a step S502 in FIG. 3. The substrate 110 extends to include an array region 1102 and a periphery region 1104 laterally enclosing the array region 1102. The insulative layer 210 may be blanketly disposed over the array region 1102 and the periphery region 1104 of the substrate 110 using a chemical vapor deposition (CVD) process or a spin-coating process. In some embodiments, the insulative layer 210 includes a non-low-k insulative material mainly composed of a silicon oxide-based insulative layer.

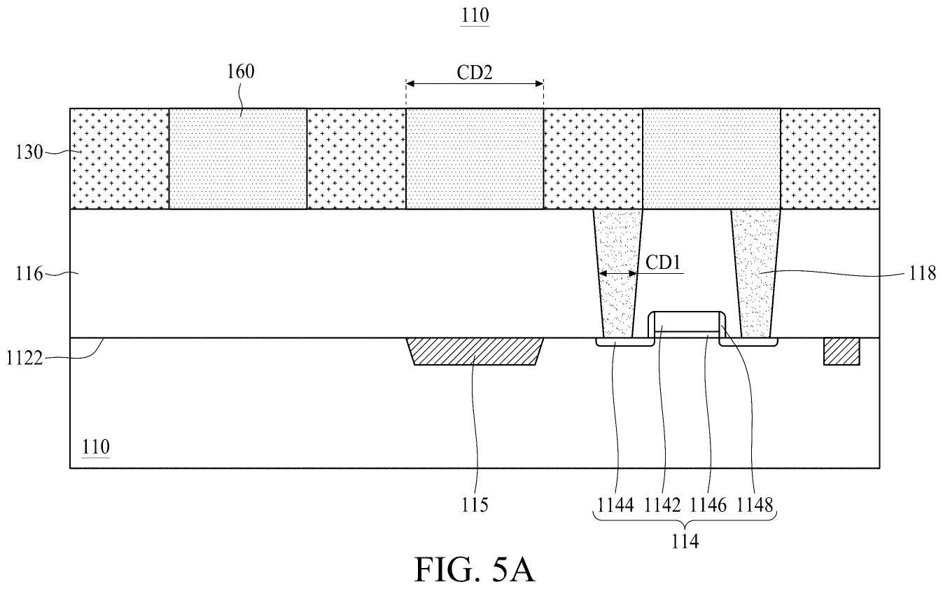

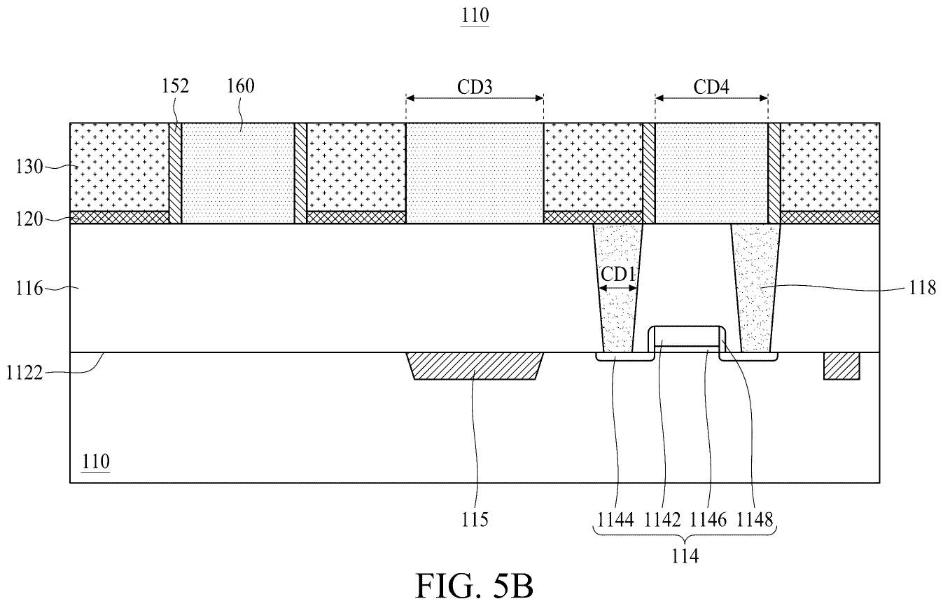

Referring to FIGS. 5A and 5B, the substrate 110 can include a semiconductor wafer 112, one or more main components 114 disposed in or on the semiconductor wafer 112, a plurality of conductive plugs 118 electrically connected to the main components 114, and a plurality of conductive blocks 160 electrically connected to the conductive plugs 118. The main components 114 and the conductive plugs 118 are created in the array area 1102.

The semiconductor wafer 112 can be made of silicon. Alternatively or additionally, the semiconductor wafer 112 may include other elementary semiconductor materials such as germanium. In some embodiments, the semiconductor wafer 112 is made of a compound semiconductor such as silicon carbide, gallium arsenic, or indium phosphide.

The main components 114 can include active components, such as transistors and/or diodes, and passive components, such as capacitors, resistors or the like. The main component 114, a planar access transistor for example, includes a gate electrode 1142 on the semiconductor wafer 112, impurity regions 1144 on either side of the gate electrode 1142, and a gate dielectric 1146 between the semiconductor wafer 112 and the gate electrode 1142. In some embodiments, the gate electrode 1142 may include, but is not limited to, doped polysilicon, or a metal-containing material comprising tungsten, titanium, or metal silicide.

The impurity regions 1144, connected to an upper surface 1122 of the semiconductor wafer 112, serve as drain and source regions of the planar access transistor. The impurity regions 1144 can be formed by introducing dopants into the semiconductor wafer 112. The introduction of the dopants into the semiconductor wafer 112 is achieved by a diffusion process or an ion-implantation process. The dopant introduction may be performed using boron or indium if the respective planar access transistor is a p-type transistor, or using phosphorous, arsenic, or antimony if the respective planar access transistor is an n-type transistor.

The gate dielectric 1146, disposed on the upper surface 1122 of the semiconductor wafer 112, is employed to maintain capacitive coupling between the gate electrode 1142 and a conductive channel between the drain and source regions. The gate dielectric 1146 may include oxide, nitride, oxynitride or high-k material. The main component 114 of the planar access transistor may further include gate spacers 1148 on sidewalls of the gate electrode 1142 and the gate dielectric 1146. The gate spacers 1148 are optionally formed by depositing a spacer material (such as silicon nitride or silicon dioxide) to cover the gate electrode 1142 and the gate dielectric 1146, and performing an anisotropic etching process to remove portions of the spacer material from horizontal surfaces of the gate electrode 1142 and the gate dielectric 1146.

In some embodiments, isolation features 115, such as shallow trench isolation (STI) features or local oxidation of silicon (LOCOS) features, can be introduced in the semiconductor wafer 112 to define and isolate various main components 114 in the semiconductor wafer 112. That is, the main components 114 are formed in the array region 1102, as shown in FIG. 4, defined by the isolation features 115.

Referring again to FIGS. 5A and 5B, the substrate 110 further includes a first dielectric layer 116 to cover the main components 114 and surround the conductive plugs 118. The first dielectric layer 116 can be formed by uniformly depositing a dielectric material, using, for example, a CVD process, to cover the upper surface 1122 of the semiconductor wafer 112 and the main components 114. Alternatively, the first dielectric layer 116 may be formed on the semiconductor wafer 112 and the main components 114 using a spin-coating process. In some embodiments, the first dielectric layer 116 may be planarized, using, for example, a chemical mechanical polishing (CMP) process, to yield an acceptably flat topology. The first dielectric layer 116 can include oxide, tetraethyl orthosilicate (TEOS), undoped silicate glass (SOG), phosphosilicate glass (PSG), borosilicate glass (BSG), borophosphosilicate glass (BPSG), fluorosilicate glass (FSG), spin-on glass (SOG), tonen silazene (TOSZ), or a combination thereof.

The conductive plugs 118 penetrate through the first dielectric layer 116 and contact the impurity regions 1144, respectively. The conductive plugs 118, including tungsten, have a critical dimension CD1, which may gradually increase at positions of increasing distance from the upper surface 1122 of the semiconductor wafer 112. Generally, the conductive plugs 118 are formed in the first dielectric layer 116 using a damascene process. The isolation features 115, the first dielectric layer 116, and the conductive plugs 118 are formed in or on the semiconductor wafer 112 during front-end-of-line processes.

The substrate 110 can further include a second dielectric layer 130 surrounding the conductive blocks 160. The conductive blocks 160 may have a same critical dimension CD2 for easy fabrication, as shown in FIG. 5A. Optically, the conductive blocks 160 may have different critical dimensions CD3 and CD4, wherein those conductive blocks 160 that have a smaller critical dimension CD4 are surrounded by liners 152 including oxide or high-k material, as shown in FIG. 5B. Referring to FIG. 5B, the substrate 110 may further include an insulating film 120 sandwiched between the first dielectric layer 116 and the second dielectric layer 130 and between the conductive plugs 118 and the second dielectric layer 130. The insulating film 120 may be employed to protect against contamination and mitigate stress at the interface between the first dielectric layer 116 and the second dielectric layer 130.

Referring again to FIGS. 4, 5A and 5B, the insulative layer 210 disposed on the substrate 110 using a vapor deposition process is formed to bury the second dielectric layer 130, the liners 152, and the conductive blocks 160. After the deposition of the insulative layer 210, a planarizing process may be performed on the insulative layer 120 to yield an acceptably flat topology. In some embodiments, the planarizing process includes a chemical mechanical polishing (CMP) process and/or a wet etching process.

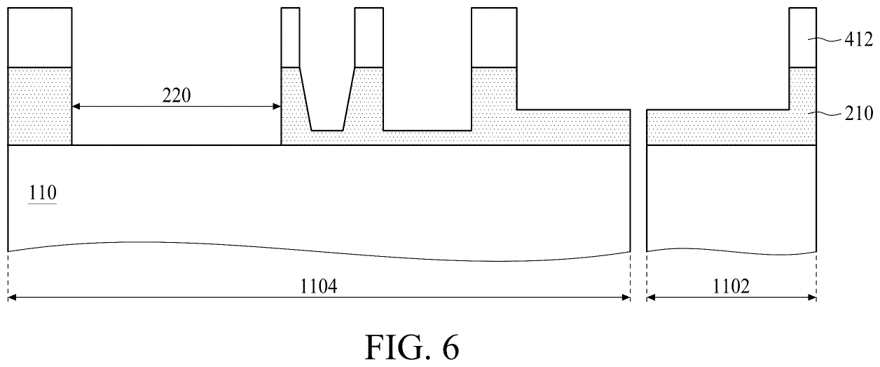

Referring again to FIG. 4, a photoresist layer 410 is applied over the entire insulative layer 210 by a spin-coating process and then dried using a soft-baking process. The photoresist layer 410, including photosensitive material, is then exposed and developed to form a feature pattern 412, shown in FIG. 6, to expose portions of the insulative layer 210. Next, a patterning process is performed to etch the insulative layer 210 through the feature pattern 412 and thus create multiple openings 220 in the insulative layer 210 according to a step S504 in FIG. 3. During the patterning process, portions of the insulative layer 210 not covered by the feature pattern 412 are removed, and at least a portion of the substrate 110 is exposed. The feature pattern 412 is removed after the openings 220 are created using an ashing process or a wet strip process, for example.

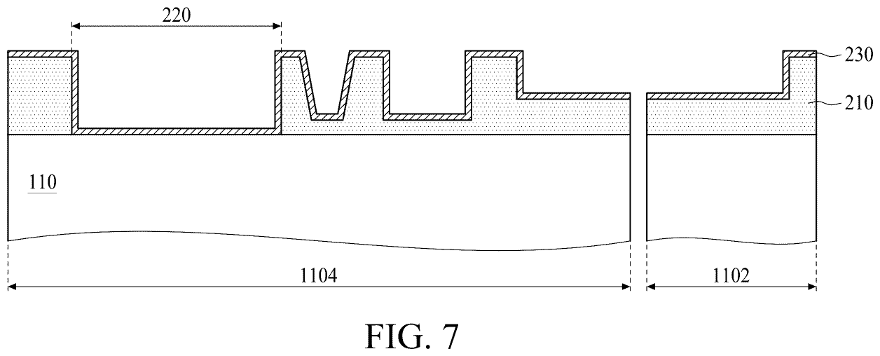

Referring to FIG. 7, an adhesion layer 230 is optionally formed, for example, using a PVD process, a CVD process, or the like in the openings 220 according to a step S506 in FIG. 3. The adhesion layer 230 is conformally deposited on the insulative layer 210 and the portion of the substrate 110 exposed to the openings 220. The adhesion layer 230 may be a single-layered structure including refractory materials (such as tantalum or titanium), refractory metal nitride, or refractory meal silicon nitrides. In alternative embodiments, the adhesion layer 230 may comprise a multi-layered structure including one or more refractory metals, refractory metal nitrides, or refractory metal silicon nitrides.

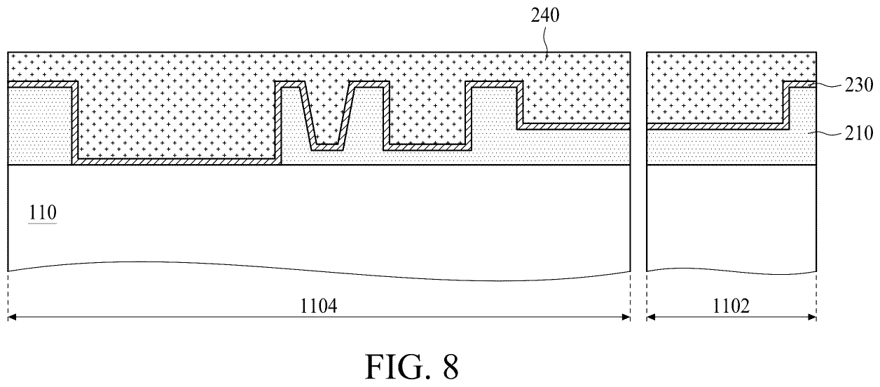

Next, the conductive material 240 is deposited to completely fill the openings 220 coated with the adhesion layer 230, as shown in FIG. 8, according to a step S508 in FIG. 3. The first conductive material 240 is uniformly deposited over the substrate 110 until the openings 220 are entirely filled. The first conductive material 240 can include tantalum, copper, copper alloy, aluminum, aluminum alloy or a combination thereof. The first conductive material 240 is formed on the adhesion layer 230 using a plating process or a CVD process.

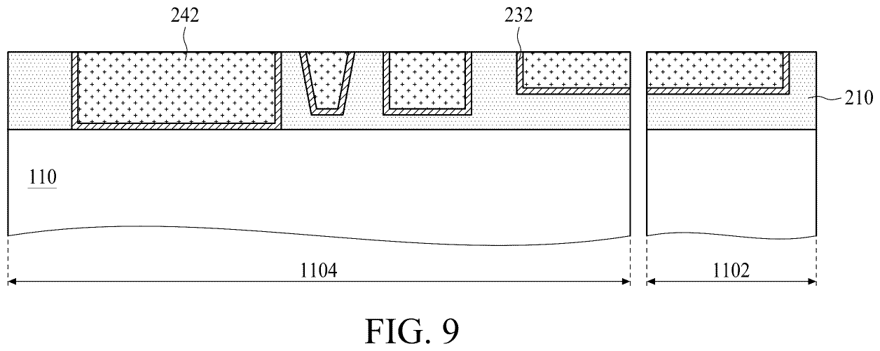

Referring to FIG. 9, a polishing process is performed to remove portions of the adhesion layer 230 and the first conductive material 240 above the openings 220 and thus form multiple metal interconnects 242 surrounded by adhesion liners 232. After the removal of the portions of the adhesion layer 230 and the superfluous conductive material 240, the insulative layer 210 is exposed. As shown in FIG. 9, some of the metal interconnects 242 surrounded by the adhesion liners 232 are disposed in the insulative layer 210, and at least one of the metal interconnects 242 surrounded by the adhesion liner 232 penetrates through the insulative layer 210. The metal interconnects 242 in the insulative layer 210 and penetrating through the insulative layer 210 are electrically connected to each other.

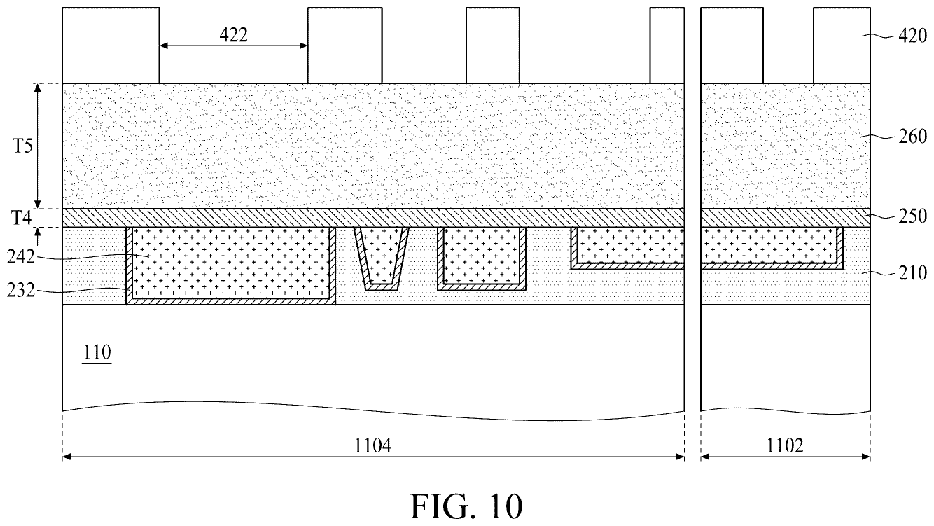

Referring to FIG. 10, a block layer 250 and an isolation layer 260 are sequentially stacked on the insulative layer 210, the adhesion liners 232, and the metal interconnects 242 according to a step S510 in FIG. 3. The block layer 250 is blanketly deposited to cover the insulative layer 210, the adhesion liners 232, and the metal interconnects 242 using a CVD process or a physical vapor deposition (PVD) process, for example. The block layer 250 may include silicon-containing dielectric, such as silicon carbide or silicon nitride. The isolation layer 260, formed using vapor deposition processes, may include silicon oxide, silicon nitride, oxynitride, BSG, low-k material, another suitable material or a combination thereof. The block layer 250 can have a thickness T4, and the isolation layer 260 has a thickness T5 greater than the thickness T4. In some embodiments, a sum of the thicknesses T4 and T5 is about 500 nanometers. After the deposition of the isolation layer 260, a planarizing process can be performed on the isolation layer 260 to yield an acceptably flat topology.

Subsequently, a pattern mask 420, including multiple windows 422, is formed on the isolation layer 260. The pattern mask 420 is formed by steps including (1) conformally coating a photosensitive material on the isolation layer 260, (2) exposing portions of the photosensitive material to radiation (not shown), and (3) developing the photosensitive material, thereby forming the windows 422 defining the pattern to etch through the isolation layer 260.

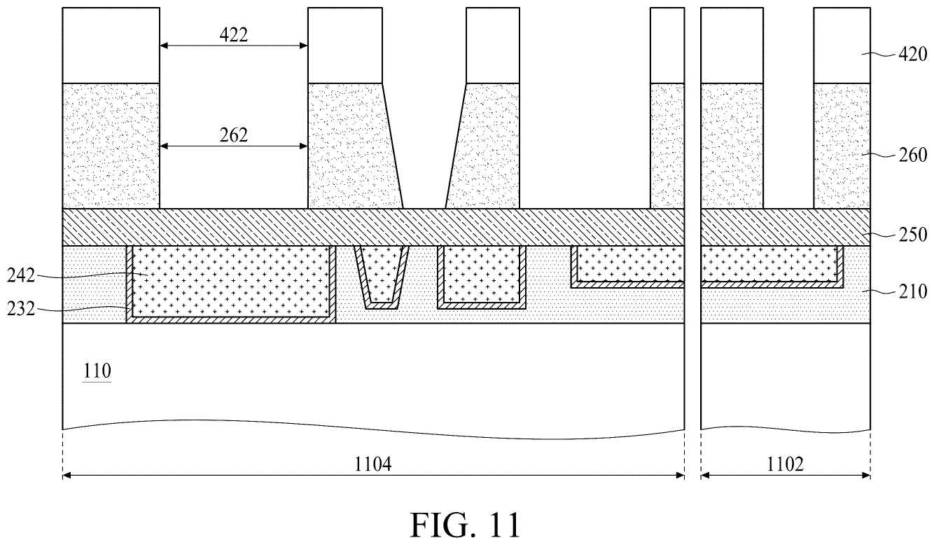

Referring to FIG. 11, an etching process is performed to remove portions of the isolation layer 260 not protected by the pattern mask 420 according to a step S512 in FIG. 3. Consequently, a plurality of trenches 262, penetrating through the isolation layer 260, are formed. That is, portions of the block layer 250 are exposed.

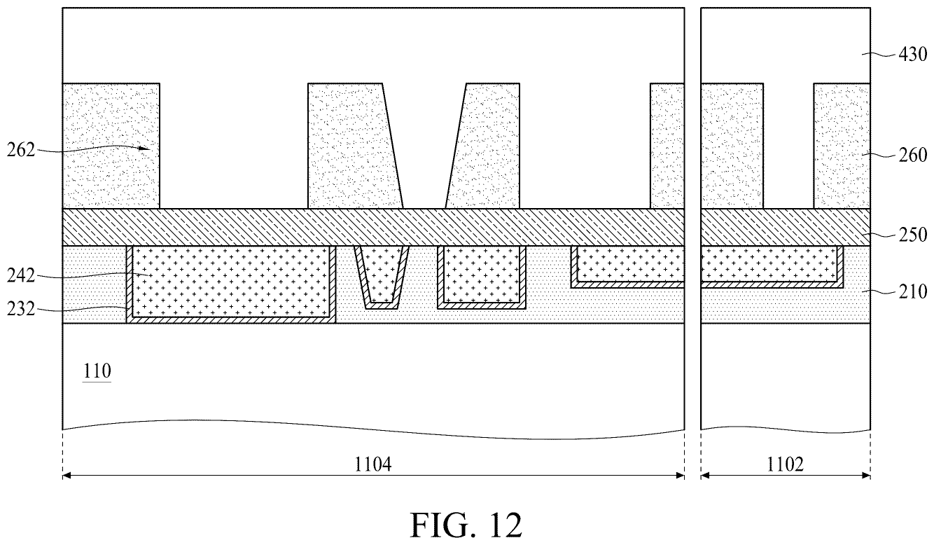

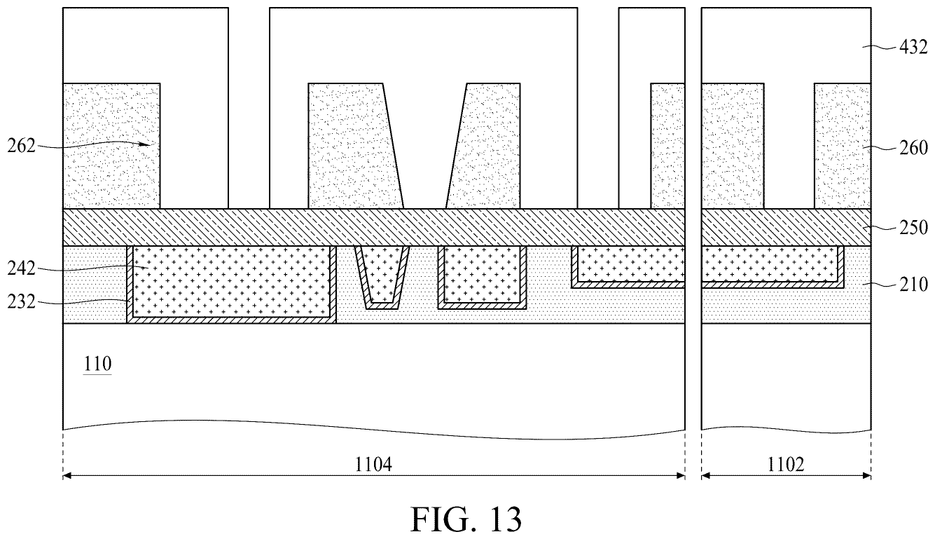

Referring to FIG. 12, a sacrificial layer 430 is applied to fill the trenches 262 according to a step S514 in FIG. 3. The sacrificial layer 430 not only fills the trenches 262 to cover the block layer 250 but also covers the isolation layer 260. The method proceeds to a step S516 shown in FIG. 3, a lithography process is performed to form multiple sacrificial blocks 432, as shown in FIG. 13. The lithography process typically involves exposure to ultraviolet and/or deep ultraviolet light, followed by subsequent baking, including a photochemical reaction which changes the solubility of the exposed regions of a photoresist material. Thereafter, an appropriate developer, typically an aqueous base solution, is used to selectively remove the photoresist material in the exposed regions (for positive-tone resist). After the lithography process, portions of the sacrificial layer 430 in the trenches 262 and over the metal interconnects 242 are removed to expose portions of the block layer 250.

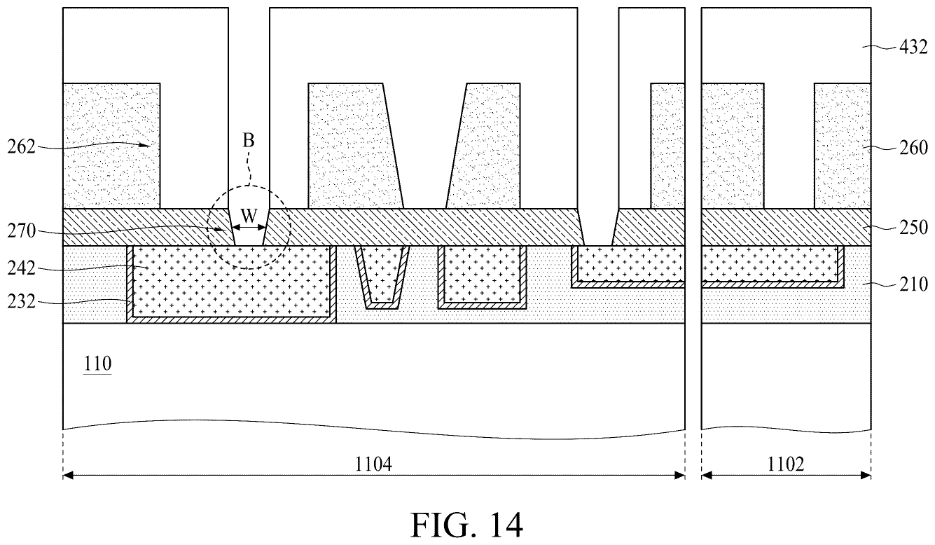

The method proceeds to a step S518 shown in FIG. 3, in which a removal process is conducted to remove portions of the block layer 250 exposed through the sacrificial blocks 432 and thus create one or more holes 270 in the block layer 250, as shown in FIG. 14. After the removal process, portions of the metal interconnects 242 are exposed.

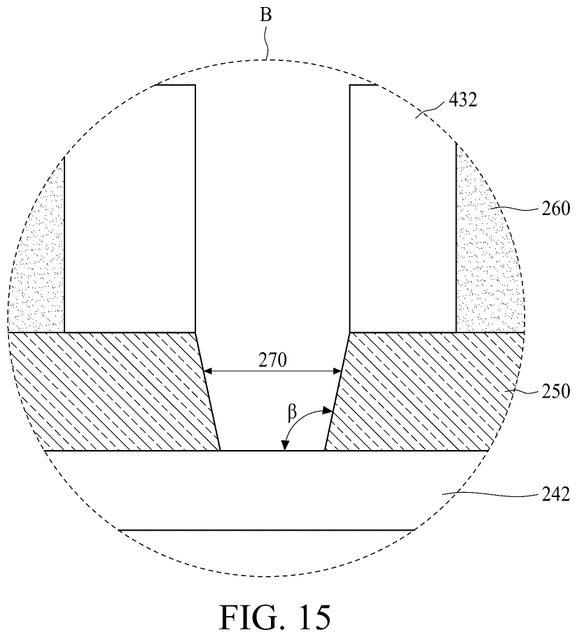

The removal process may include a dry plasma etching process. In some embodiments, the removal process for creating the holes 270, having a width W that gradually increases at positions of increasing distance from the metal interconnects 242, uses a process gas that comprises a mixture of carbon tetrafluoride (CF₄) and nitrogen (N₂). In some embodiments, a ratio of the carbon tetrafluoride to the nitrogen is in a range between 1.5:1 and 1.8:1. A pressure in a chamber for performing the removal process (an operating pressure) is in a range between 50 and 150 metric ton, and a direct current superposition (DCS) voltage applied during the removal process is in a range between 100 and 300 volts. Referring to FIG. 15, an included angle β between the block layer 250 and the metal interconnect 242 is greater than 90 degrees. The included angle β may increase as the pressure in the chamber for performing the removal process increases. In addition, the included angle β may increase as the DCS voltage decreases. Furthermore, the included angle β may increase as the ratio of the carbon tetrafluoride to nitrogen increases. After the creation of the holes 270, an ashing process or a wet strip process may be used to remove the sacrificial block 432, wherein the wet strip process may chemically alter the sacrificial block 432 so that it no longer adheres to the block layer 250 and the isolation layer 260.

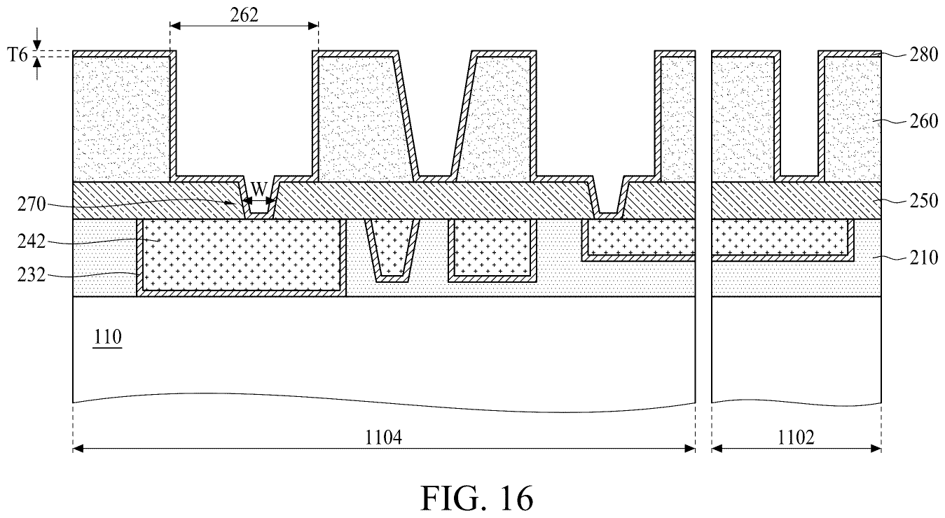

Referring to FIG. 16, a diffusion barrier layer 280 may be formed, for example, using a PVD process, a CVD process, or the like in the trench 262 and the holes 270 connected to the trench 262 according to a step S520 in FIG. 3. The diffusion barrier layer 280 is conformally deposited on the isolation layer 260, and on portions of the block layer 250 and the metal interconnects 242 exposed to the holes 270. The diffusion barrier layer 280 may have a thickness T6. In a predetermined deposition time, greater values of the width W of the hole 270 corresponding to greater values of the thickness T6. The diffusion barrier layer 280 may be a single-layered structure including refractory materials (such as tantalum or titanium), refractory metal nitride, or refractory meal silicon nitrides. In alternative embodiments, the diffusion barrier layer 280 may comprise a multi-layered structure including one or more refractory metals, refractory metal nitrides, or refractory metal silicon nitrides.

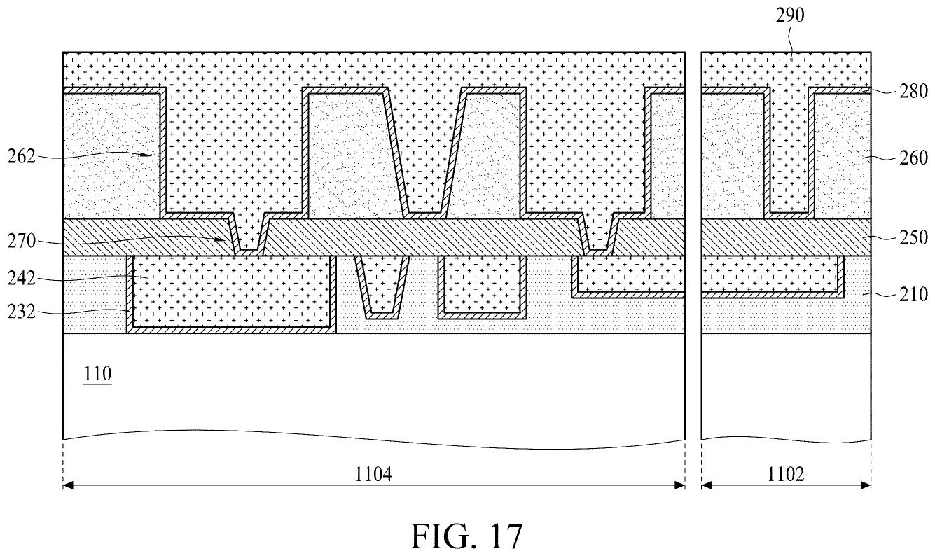

The method 500 then proceeds to a step S522, in which a plating process is performed to fill the trenches 262 and the holes 270 with a second conductive material 290, as shown in FIG. 17. The second conductive material 290 can be conformally and uniformly deposited, by way of an electroplating process, for example, on the metal interconnects 242 and the block layer 250 until the holes 270 and the trenches 262 are completely filled. The second conductive material 290 can include tantalum, copper, aluminum or the like. In some embodiments, the second conductive material is the same as the first conductive material.

Next, at least one removal process is performed to remove the diffusion barrier layer 280 and the second conductive material 290 above the trenches 262, thereby exposing the isolation layer 260. Consequently, multiple conductive features 292, surrounded by the diffusion barrier liner 282, are formed as shown in FIG. 1.

In conclusion, with the configuration of the semiconductor device 10, the thickness T2 of the neck portion 296 of the conductive feature 292 for connecting the head portion 294 of the conductive feature 292 to the metal interconnect 242 can be adjusted by precisely controlling an etchant, the pressure, and the direct current superposition voltage applied to a chamber for conducting an etching process to define a shape of the neck portion 296. Therefore, the resistance of the neck portion 296 and thus the resistance of the wiring structure 100 formed during the back-line-of-line processes can be effectively controlled.

One aspect of the present disclosure provides a semiconductor device. The semiconductor device comprises a substrate and a wiring structure. The wiring structure comprises at least one metal interconnect, at least one conductive feature and at least one diffusion barrier liner. The metal interconnect is disposed on the substrate, and the conductive feature is disposed on the metal interconnect. The conductive feature has a head portion and a neck portion between the metal interconnect and the head portion, wherein the neck portion has a first critical dimension, which gradually decreases at positions of increasing distance from the head portion. The conductive feature is surrounded by the diffusion barrier liner.

One aspect of the present disclosure provides a method of manufacturing a semiconductor device. The method comprises steps of providing a plurality of metal interconnects; disposing a block layer on the metal interconnects; disposing an isolation layer on the block layer; forming at least one trench in the isolation layer; forming at least one hole penetrating through the block layer and connecting to the trench, wherein the hole has a width, which gradually increases at positions of increasing distance from the metal interconnect; and depositing a conductive material in the trench and the hole.

Although the present disclosure and its advantages have been described in detail, it should be understood that various changes, substitutions and alterations can be made herein without departing from the spirit and scope of the disclosure as defined by the appended claims. For example, many of the processes discussed above can be implemented in different methodologies and replaced by other processes, or a combination thereof.

Moreover, the scope of the present application is not intended to be limited to the particular embodiments of the process, machine, manufacture, composition of matter, means, methods and steps described in the specification. As one of ordinary skill in the art will readily appreciate from the present disclosure, processes, machines, manufacture, compositions of matter, means, methods or steps, presently existing or later to be developed, that perform substantially the same function or achieve substantially the same result as the corresponding embodiments described herein, may be utilized according to the present disclosure. Accordingly, the appended claims are intended to include within their scope such processes, machines, manufacture, compositions of matter, means, methods and steps.

What is claimed is:

1. A method of manufacturing a semiconductor device, comprising:
providing a plurality of metal interconnects on a substrate;
disposing a block layer on the metal interconnects;
disposing an isolation layer on the block layer;
forming at least one trench in the isolation layer;
forming at least one hole penetrating through the block layer and connected to the trench, wherein the hole has a width, which gradually increases at positions of increasing distance from the metal interconnect;
depositing a diffusion barrier layer in the trench and the hold; and
depositing a conductive material on the diffusion barrier layer.

2. The method of claim 1, wherein an included angle between the block layer and the one of the metal interconnects is greater than 90 degrees.

3. The method of claim 2, wherein in a predetermined deposition time, greater values of the width corresponding to greater values of a thickness of the diffusion barrier layer, and a direct current superposition voltage for conducting the removal process is between 100 and 300 volts.

4. The method of claim 1, wherein the formation of the hole penetrating through the block layer and connected to the trench comprises:
forming a sacrificial layer on the isolation layer and in the trench;
performing a lithography process to remove a portion of the sacrificial layer in the trench and over the metal interconnect, and thus form sacrificial blocks; and
performing a removal process to remove a portion of the block layer exposed through the trench.

5. The method of claim 4, wherein the removal process uses a process gas that comprises a mixture of carbon tetrafluoride and nitrogen.

6. The method of claim 4, wherein a ratio of the carbon tetrafluoride to the nitrogen is in a range between 1.5:1 and 1.8:1.

7. The method of claim 6, wherein greater values of the ratio correspond to greater values of the width of the hole.

8. The method of claim 3, wherein an operating pressure for conducting the removal process is in a range between 50 and 150 metric tons, and greater values of the pressure correspond to greater values of the width of the hole.
